(19) United States
(12) Patent Application Publication
(10) Pub. No.: US 2025/0159385 A1
(43) Pub. Date: May 15, 2025

(54) REMOTE RADIO HEAD MOUNTING BRACKET AND METHOD FOR USE

(71) Applicant: Valmont Industries, Inc., Omaha, NE (US)

(72) Inventor: Joseph E. Trimble, Valparaiso, IN (US)

(73) Assignee: Valmont Industries, Inc., Omaha, NE (US)

(21) Appl. No.: 18/938,368

(22) Filed: Nov. 6, 2024

Related U.S. Application Data
(60) Provisional application No. 63/597,424, filed on Nov. 9, 2023.

(51) Int. Cl. H04Q 1/02

(52) U.S. Cl. CPC H04Q 1/09

(57) ABSTRACT

An RRU bracket assembly for attachment to a tower frame pole. According to a preferred embodiment, the RRU bracket assembly of the present invention includes a front bracket plate and a rear bracket plate placed on either side of the frame pole and which are secured to the frame pole via one or more securing rods which are inserted through the front and rear bracket plates and tightened to create a frictional fit with the frame pole. The front bracket plate preferably includes an upper connection plate and a lower connection plate with each connection plate having bolt slots for allowing adjustable spacing between a right side wall and a left side wall.

### RELATED APPLICATIONS

The present application claims priority to U.S. Provisional Application No. 63/597,424 filed Nov. 9, 2023.

### FIELD OF INVENTION

The present invention is related in general to telecommunication tower design and, in particular, to a remote radio head mounting bracket and method for use.

### BACKGROUND OF THE INVENTION

A remote radio unit (RRU), also called a remote radio head (RRH), is a remote radio transceiver within a telecom network that connects to an operator radio control panel via an electrical or wireless interface. In wireless system technologies, RRH equipment is used to extend the coverage of different telecom systems especially when mounted at elevation.

Each RRU is a complex and expensive piece of equipment. Most commonly, each RRU contains the base station's RF circuitry plus analog-to-digital/digital-to-analog converters and a variety of other sensitive electronics. For effective use, RRUs are most commonly attached to frame elements of vertical towers which allow the RRUs some distance from ground clutter and other EM interference sources.

Proper installation and secure mounting of each RRU is important for reliable operation and physical protection of the device. Because of this, proper attachment is crucial. At the same time, a single telecom operator may be responsible for thousands of individual RRUs which each must be individually installed and maintained by individual telecom engineers in the field. This attachment process requires significant man hours to secure each RRU while keeping each unit at a proper orientation.

Still further, where properly tapered vertical towers can be constructed and maintained, there exists the additional problem of efficiently connecting lateral spanning elements and wall elements to the tapered tower elements. Such attachment may require cranes, ropes, pulleys, and human exertion at elevation, in remote locations and in a wide variety of weather conditions. Still further, there are limitations which require the additional elements to match tower dimensions and be lightweight, easy to connect and add to the overall stability of the tower. Because of these reasons, tower elements such as RRUs are costly to install, restricted in size, and limited in variation and added benefits.

### SUMMARY OF THE DISCLOSURE

To overcome the limitations of the prior art, the present invention provides an RRU bracket assembly for attachment to a tower frame pole. According to a first preferred embodiment, the RRU bracket assembly of the present invention preferably includes a front bracket plate and a rear bracket plate. The front bracket plate preferably includes an upper connection plate and a lower connection plate.

According to a first preferred method of installation, the front and rear bracket plates are preferably placed on either side of the frame pole and secured to the frame pole via one or more securing rods which are inserted through the front and rear bracket plates and tightened to create a frictional fit with the frame pole.

According to a first preferred embodiment, the RRU bracket assembly preferably includes a left side wall and right side wall which are attached to the upper and lower connection plates of the front bracket plate.

According to a further preferred embodiment, the left side wall preferably includes a left wall upper weldment, a left wall lower weldment and a left front wall weldment. Further, the right side wall preferably includes a right wall upper weldment, a right wall lower weldment and a right front wall weldment.

According to a further preferred embodiment, the left side wall is preferably attached to the front bracket plate with a left upper securing bolt which is inserted through the left wall upper weldment and the upper connection plate. According to a further preferred embodiment, the left side wall is further attached to the front bracket plate with a left lower securing bolt which is inserted through the left wall lower weldment and the lower connection plate.

According to a further preferred embodiment, the right side wall is preferably attached to the front bracket plate with a right upper securing bolt which is inserted through the right wall upper weldment and the upper connection plate. According to a further preferred embodiment, the right side wall is further attached to the front bracket plate with a right lower securing bolt which is inserted through the right wall lower weldment and the lower connection plate.

According to a further preferred embodiment, the left side wall and the right side wall are preferably connected via one or more front lateral bolts which are preferably inserted through the left front wall weldment and the right front wall weldment.

According to a preferred embodiment, the front bracket plate preferably includes an upper connection plate and a lower connection plate with each connection plate having bolt slots for allowing adjustable spacing between the right side wall and the left side wall.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### BRIEF DESCRIPTION OF THE DRAWINGS

Elements in the figures have not necessarily been drawn to scale in order to enhance their clarity and to improve the understanding of the various elements and embodiments of the invention. Furthermore, elements that are known to be common and well understood to those in the industry are not depicted in order to provide a clear view of the various embodiments of the invention. Thus, it should be understood that the drawings are generalized in form in the interest of clarity and conciseness.

FIG. 1 illustrates a perspective view of a pair of RRU bracket assemblies attached to a tower element in accordance with a first preferred embodiment of the present invention.

FIG. 2 illustrates a side view of the RRU bracket assemblies shown in FIG. 1.

FIG. 3 illustrates a front view of the RRU bracket assemblies shown in FIG. 1.

FIG. 4 is a perspective view of an RRU bracket assembly in accordance with a first preferred embodiment of the present invention.

FIG. 5 illustrates a top-down view of the RRU bracket assembly shown in FIG. 4.

FIG. 6 illustrates an enlarged, cut-away view of a first section of the RRU bracket assembly as indicated in FIG. 4.

FIG. 7 illustrates an enlarged, cut-away view of a second portion of the RRU bracket assembly as indicated in FIG. 4.

FIG. 8 illustrates a perspective view of a pair of RRU bracket assemblies attached to a tower element in accordance with an alternative preferred embodiment of the present invention.

FIG. 9 illustrates a side, perspective view of one of the two RRU bracket assemblies shown in FIG. 8.

### DETAILED DESCRIPTION OF THE DRAWINGS

Various inventive features are described below that can each be used independently of one another or in combination with other features. However, any single inventive feature may not address any of the problems discussed above or only address one of the problems discussed above. Further, one or more of the problems discussed above may not be fully addressed by any of the features described below.

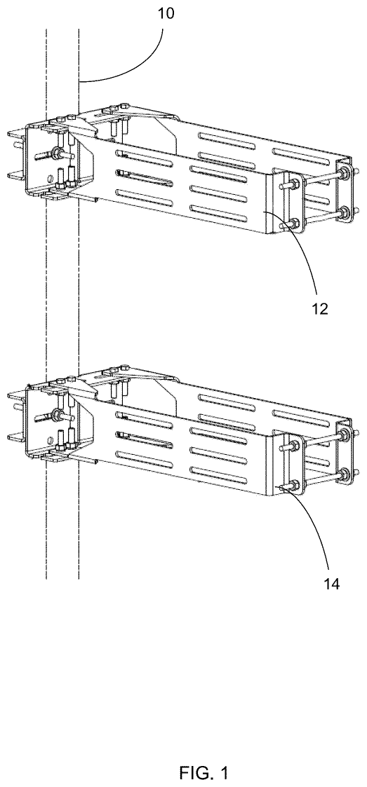

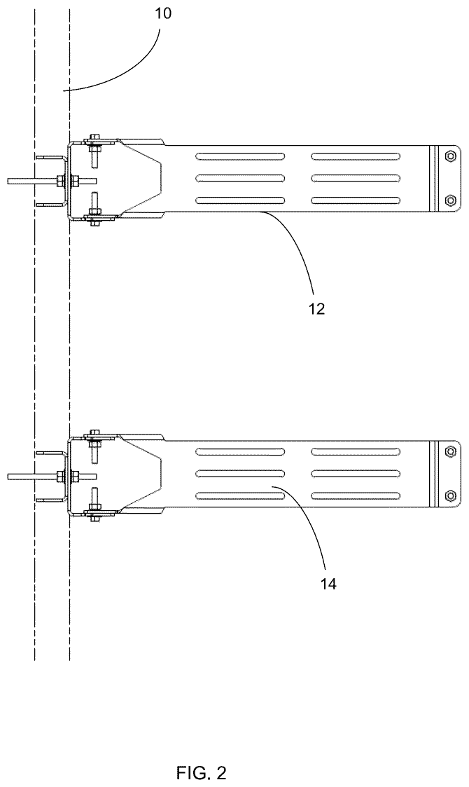

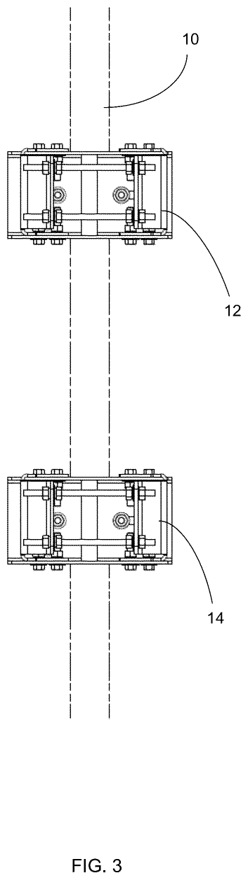

With reference now to FIGS. 1-5, an exemplary RRU bracket assembly in accordance with a first preferred embodiment of the present invention shall now be discussed. As shown in FIG. 1, the RRU bracket assembly 12, 14 of the present invention may preferably be attached to various telecom tower frame members 10 without limitation. As shown in FIG. 1, the RRU bracket assembly 12 of the present may preferably be attached to a vertical pole 10 so that the RRU bracket assembly 12 extends laterally out from the tower frame member 10. As further shown in FIG. 1, multiple RRU bracket assemblies 12, 14 may preferably be attached to a single frame member 10. FIG. 2 illustrates a side view of the RRU bracket assemblies 12, 14 shown in FIG. 1. FIG. 3 illustrates a front view of the same bracket RRU bracket assemblies 12, 14.

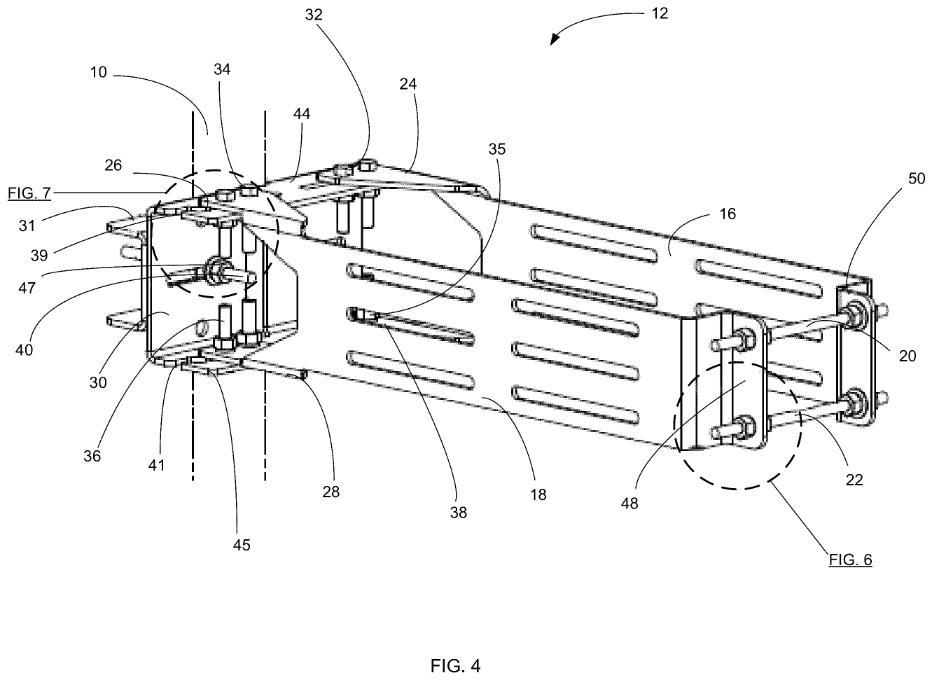

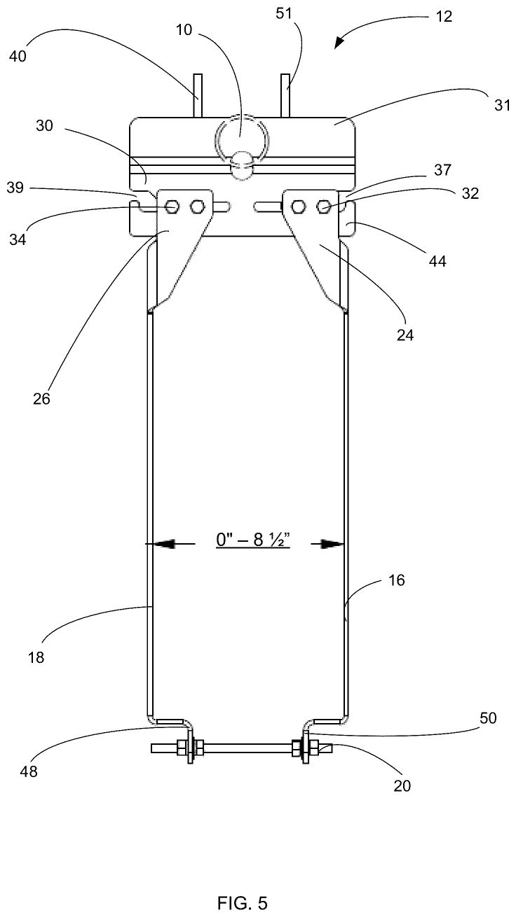

With reference now to FIGS. 4 and 5, detailed perspective and top-down views of an exemplary RRU bracket assembly 12 shall now be discussed. As shown, an RRU bracket assembly 12 of the present invention may include a front bracket plate 30 and a rear bracket plate 31 which are made to be connected together via one or more securing rods 40, 51 (shown in FIG. 5). The securing rods 40, 51 may preferably be tightened (via securing bolts 47 or the like) to compress a given tower element 10 between the front and rear bracket plates 30, 31 and thus form a frictional fit to secure the RRU bracket assembly 12 to the tower element 10.

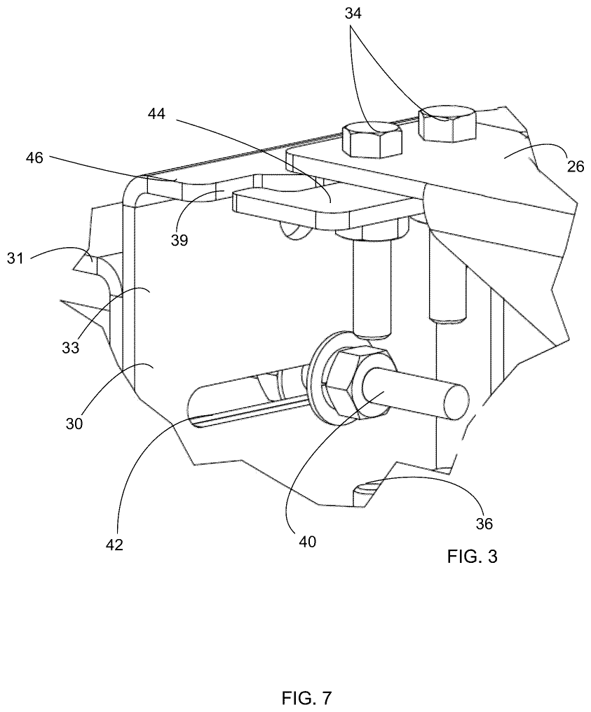

As shown, the bracket assembly 12 preferably includes a left side wall 16 and right sidewall 18. The left side wall 16 preferably extends from a left wall upper weldment 24 and a left wall lower weldment 38 and terminates at a left front wall weldment 50. Similarly, the right side wall 18 preferably extends from a right wall upper weldment 26 and a right wall lower weldment 28 and terminates at a right front wall weldment 48. As shown in FIG. 5, the front bracket plate 30 preferably includes an upper connection plate 44 which horizontally extends out from the vertical front face 33 (shown in FIG. 7) of the front bracket plate 30. As further shown, the left side wall 16 may preferably be attached to the front bracket plate 30 via one or more left upper securing bolts 32 inserted through the left wall upper weldment 24 and the upper connection plate 44 of the front bracket plate 30. Similarly, the right side wall 18 may preferably be attached to the front bracket plate 30 via one or more right upper securing bolts 34 inserted through the right wall upper weldment 26 and the upper connection plate 44.

The left side wall 16 may preferably be further connected to the front bracket plate via one or more lower securing bolts 35 which are inserted through a left wall lower weldment 38 and the lower connection plate 45. The right side wall 18 may preferably be further connected to the front bracket plate 30 via one or more right lower securing bolts 36 inserted through the right wall lower weldment 28 and the lower connection plate 45.

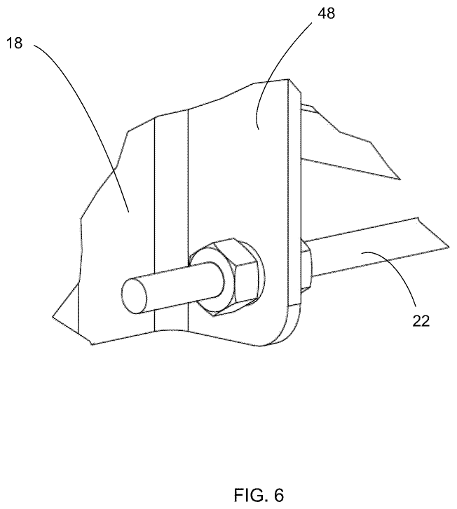

The right and left front wall weldments 48, 50 are preferably attached to each other via a front upper lateral bolt 20 and a front lower lateral bolt 22 which may preferably be inserted through the right and left front wall weldments and bolted in place. FIG. 6 provides an enlarged view of the connection between the right front wall weldment 48 and the front lower lateral bolt 22.

Referring now to FIG. 7, a detailed view of the connection point between the right wall upper weldment 26 and the upper connection plate 44 is shown. As shown, the upper connection plate 44 may preferably extend from the front bracket plate top surface 46 of the front bracket plate 30. As further shown, the front bracket plate 30 may preferably include one or more securing rod slots 42 to allow the securing rods 40 (and 51 not shown) to extend through the front bracket plate 30. As further shown in FIG. 7 and as discussed above, the right side wall 18 may preferably be attached to the front bracket plate 30 via one or more right upper securing bolts 34 inserted through the right wall upper weldment 26 and the upper connection plate 44. To allow this insertion, one or more upper left and right upper bolt slots 39 (and 37 shown in FIG. 5) may preferably be formed within the upper connection plate 44 and/or between the front bracket plate 30 and the upper connection plate 44.

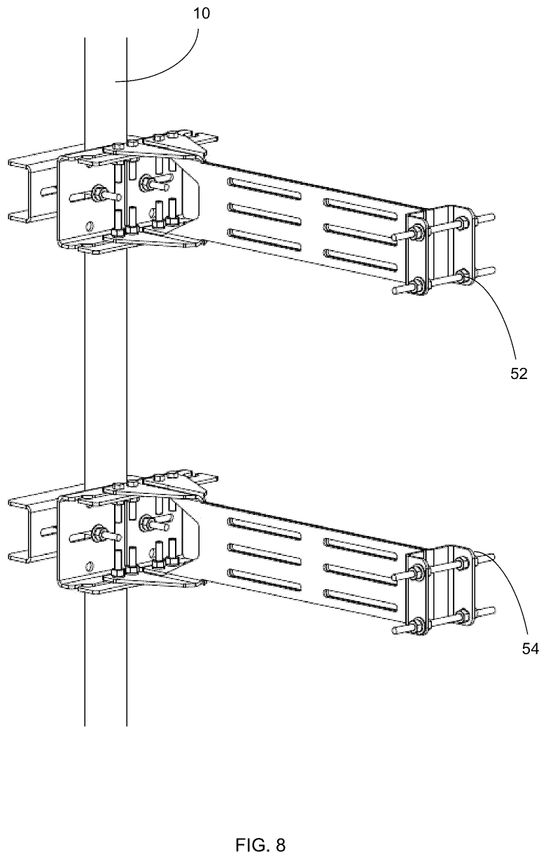

Referring now to FIG. 8, a first alternative embodiment of the present invention shall now be discussed. As shown in FIG. 8, the elements of the RRU bracket assemblies discussed above may be arranged to produce the alternative RRU bracket assemblies 52, 54 of the present invention. Specifically, the elements may be alternatively configured so the right and left side walls 16, 18 are arranged in contact with each other or with minimal space between the walls 16, 18.

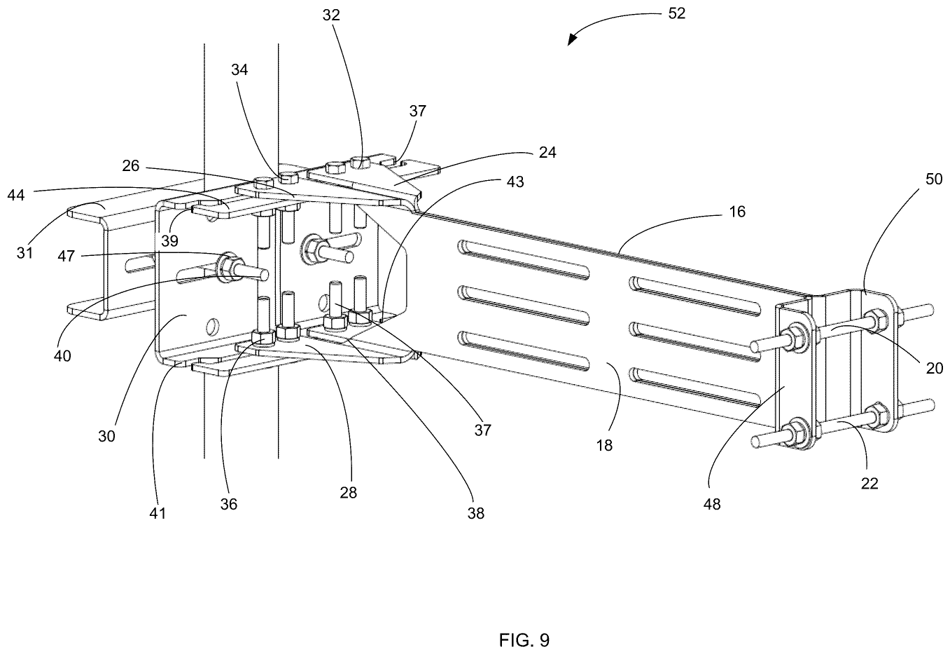

Referring now to FIG. 9, such an exemplary RRU bracket assembly 52 may be configured so that the right wall upper weldment 26 and the right wall lower weldment 28 are moved/positioned towards the center of the front bracket plate 30. In this arrangement, the right upper securing bolts 34 and right lower securing bolts 36 may preferably be inserted or slid within the right upper bolt slot 39 and the right lower bolt slot 41 respectively so that they are positioned towards the center of the front bracket plate 30.

Mirroring the position of the right side wall 18, the left side wall 16 may be similarly positioned by moving/positioning the left wall upper weldment 24 and the left wall lower weldment 38 towards the center of the front bracket plate 30. In this arrangement, the left upper securing bolts 32 and left lower securing bolts 37 may preferably be inserted or slid within the left upper bolt slot 37 and the left lower bolt slot 43 respectively so that they are positioned towards the center of the front bracket plate 30. In this way, the left and right side walls 16, 18 may preferably be positioned flush or nearly flush to one another. In accordance with further alternative embodiments, the distance between the right and left side wall 16, 18 may be varied and set to any given distance by inserting or sliding the respective upper and lower securing bolts 32, 34, 36, 38 within various positions within the respective bolt slots 37, 39, 41, 43.

Unless the context clearly requires otherwise, throughout the description and the claims, the words ‘comprise,’ ‘comprising,’ and the like are to be construed in an inclusive sense as opposed to an exclusive or exhaustive sense, that is to say, in a sense of ‘including, but not limited to.’ Words using the singular or plural number also include the plural or singular number respectively. Additionally, the words, ‘herein,’ ‘hereunder,’ ‘above,’ ‘below,’ and words of similar import refer to this application as a whole and not to any particular portions of this application. When the word ‘or’ is used in reference to a list of two or more items, that word covers all of the following interpretations of the word: any of the items in the list, all of the items in the list and any combinations of the items in the list.

The above descriptions of illustrated embodiments of the above apparatus are not intended to be exhaustive or to limit the apparatus to the precise form disclosed. While specific embodiments of, and examples for, the apparatus are described herein for illustrative purposes, various equivalent modifications are possible within the scope of the disclosed apparatus as those skilled in the relevant art will recognize.

In the following claims, the terms used should not be construed to limit the apparatus to the specific embodiments disclosed in the specification and the claims. The disclosed apparatus is not intended to be limited by the disclosure, but instead the scope of the apparatus is to be determined entirely by the claims.

What is claimed is:

1. An RRU bracket assembly for attachment to a tower frame pole, wherein the bracket assembly comprises:
a front bracket plate; wherein the front bracket plate comprises a vertical front face, a rod securing slot, an upper connection plate and a lower connection plate;
a rear bracket plate;
a plurality of securing rods; wherein the plurality of securing rods extend through the front bracket plate and the rear bracket plate; wherein the front bracket plate and the rear bracket plate are spaced a first distance apart on either side of the tower frame pole; wherein the plurality of securing rods extend through the front bracket plate and the rear bracket plate; wherein the securing rods are configured to reduce the first distance and to form a frictional fit with the tower frame pole;
a left side wall; wherein the left side wall comprises a left wall upper weldment, a left wall lower weldment and a left front wall weldment;
a right side wall; wherein the right side wall comprises a right wall upper weldment, a right wall lower weldment and a right front wall weldment;
wherein the left side wall is attached to the front bracket plate with a left upper securing bolt; wherein the left upper securing bolt is inserted through the left wall upper weldment and the upper connection plate; wherein the left side wall is further attached to the front bracket plate with a left lower securing bolt; wherein the left lower securing bolt is inserted through the left wall lower weldment and the lower connection plate;
wherein the right side wall is attached to the front bracket plate with a right upper securing bolt; wherein the right upper securing bolt is inserted through the right wall upper weldment and the upper connection plate; wherein the right side wall is further attached to the front bracket plate with a right lower securing bolt; wherein the right lower securing bolt is inserted through the right wall lower weldment and the lower connection plate;
a front upper lateral bolt; and
a front lower lateral bolt; wherein the front upper lateral bolt and front lower lateral bolt extend through the left front wall weldment and the right front wall weldment.

2. The mounting bracket assembly of claim 1, wherein said front bracket plate comprises bolt slots for adjustable positioning of said left and right side walls.

3. The mounting bracket assembly of claim 2, wherein said front bracket plate includes an alignment guide.

4. The mounting bracket assembly of claim 3, wherein the rear bracket plate comprises gripping surfaces.

5. The mounting bracket assembly of claim 4, wherein the front upper lateral bolt and the front lower lateral bolt are configured to be adjustable in length.

6. The mounting bracket assembly of claim 1, wherein the assembly further comprises: a first securing rod nut and a second rod securing nut; wherein the first securing rod nut and the second rod securing nuts are configured to tighten and compress a tower frame element between the front and rear bracket plates to form a frictional fit.

7. A method for providing a mounting surface on a tower frame pole, the method comprising:
providing an RRU bracket assembly as claimed in claim 1;
positioning a front bracket plate and a rear bracket plate on opposite sides of a tower element;
inserting one or more securing rods through said front and rear bracket plates;
tightening said securing rods to create a frictional fit with the tower frame pole;
attaching a left side wall and a right side wall to said front bracket plate using securing bolts; and
securing said left and right side walls to one another with one or more front lateral bolts.

8. The method of claim 7, further comprising: tightening the securing rods by rotating securing bolts to increase compression between the front and rear bracket plates.
